(19) United States
(12) Patent Application Publication
(10) Pub. No.: US 2024/0274559 A1
(43) Pub. Date: Aug. 15, 2024

(54) ELECTRONIC DEVICE

(71) Applicant: Innolux Corporation, Miaoli County (TW)

(72) Inventor: Chia-Ping Tseng, Miaoli County (TW)

(73) Assignee: Innolux Corporation, Miaoli County (TW)

(21) Appl. No.: 18/411,050

(22) Filed: Jan. 12, 2024

Related U.S. Application Data
(60) Provisional application No. 63/444,559, filed on Feb. 10, 2023.

(30) Foreign Application Priority Data
Sep. 25, 2023 (CN) 202311242672.9

(51) Int. Cl. H01L 23/00

(52) U.S. Cl. CPC H01L 24/06; H01L 24/02; H01L 24/05; H01L 24/13; H01L 24/14; H01L 24/16; H01L 2224/02373; H01L 2224/02375; H01L 2224/02381; H01L 2224/0239; H01L 2224/05008; H01L 2224/05073; H01L 2224/05082; H01L 2224/05083; H01L 2224/05111; H01L 2224/05147; H01L 2224/05186; H01L 2224/05547; H01L 2224/05548; H01L 2224/05567; H01L 2224/05573; H01L 2224/05647; H01L 2224/05655; H01L 2224/05666; H01L 2224/06102; H01L 2224/06505; H01L 2224/13021; H01L 2224/13082; H01L 2224/13111; H01L 2224/13139; H01L 2224/13144; H01L 2224/13147; H01L 2224/13155; H01L 2224/1357; H01L 2224/13644; H01L 2224/1403; H01L 2224/16145; H01L 2224/16265; H01L 2924/01029; H01L 2924/0132; H01L 2924/04941

(57) ABSTRACT

An electronic device includes a substrate, a first metal layer, a second metal layer, a third metal layer, pads, an electronic element, and a switching element. The first metal layer, the second metal layer, and the third metal layer are disposed on the substrate. The pads are disposed on the substrate, including a first pad, a second pad, and a third pad. The electronic element is disposed on the substrate and connected to the first pad. The switching element is disposed on the substrate and connected to the second pad. The second metal layer is disposed between the first metal layer and the third metal layer. The first pad and the first metal layer belong to the same layer. The first pad is electrically connected to the second pad through the first metal layer and the third metal layer.

### CROSS-REFERENCE TO RELATED APPLICATION

This application claims the priority benefits of U.S. provisional application Ser. No. 63/444,559, filed on Feb. 10, 2023 and China application serial no. 202311242672.9, filed on Sep. 25, 2023. The entirety of each of the above-mentioned patent applications is hereby incorporated by reference herein and made a part of this specification.

### BACKGROUND

### Technical Field

The disclosure relates to an electronic device, specifically to an electronic device that effectively reduces production cost.

### Description of Related Art

In conventional techniques, a driver element of electronic device, e.g., a thin-film transistor (TFT), is directly manufactured on a glass substrate. However, this approach leads to more layers stacked on the glass substrate, more complex manufacture procedures, and higher manufacturing cost.

### SUMMARY

The disclosure provides an electronic device that effectively reduces production cost.

An electronic device according to an aspect of the disclosure includes a substrate, a first metal layer, a second metal layer, a third metal layer, multiple pads, an electronic element, and a switching element. The first metal layer is disposed on the substrate. The second metal layer is disposed on the substrate. The third metal layer is disposed on the substrate. The pads are disposed on the substrate and include a first pad, a second pad, and a third pad. The electronic element is disposed on the substrate and connected to the first pad. The switching element is disposed on the substrate and connected to the second pad. The second metal layer is disposed between the first metal layer and the third metal layer. The first pad and the first metal layer belong to the same layer, and the first pad is electrically connected to the second pad through the first metal layer and the third metal layer.

In light of the foregoing, in the embodiments of the disclosure, the switching element is connected to the second pad through bonding, the first pad and the first metal layer belong to the same layer and the first pad is electrically connected to the second pad through the first metal layer and the third metal layer. Through bonding of the switching element and design of sharing the same layer, the electronic device of the disclosure effectively reduces production cost.

To make the previously mentioned features and advantages of the disclosure more comprehensible, embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view illustrating an electronic device according to an embodiment of the disclosure.

FIG. 1B is a schematic cross-sectional view taken along line A-A and line B-B in FIG. 1A.

FIG. 1C is a schematic cross-sectional view taken along line I-I in FIG. 1A.

FIG. 2 is a schematic top view illustrating an electronic device according to another embodiment of the disclosure.

FIG. 3 is a schematic cross-sectional view illustrating an electronic device according to another embodiment of the disclosure.

FIG. 4 is a schematic cross-sectional view illustrating an electronic device according to another embodiment of the disclosure.

FIG. 5 is a schematic cross-sectional view illustrating an electronic device according to another embodiment of the disclosure.

FIG. 6 is a schematic cross-sectional view illustrating an electronic device according to another embodiment of the disclosure.

FIG. 7A is a schematic top view illustrating an electronic device according to an embodiment of the disclosure.

FIG. 7B is a schematic cross-sectional view taken along line C-C and line D-D in FIG. 7A.

FIG. 8A is a schematic top view illustrating an electronic device according to an embodiment of the disclosure.

FIG. 8B is a schematic cross-sectional view taken along line E-E and line F-F in FIG. 8A.

FIG. 9 is a partial schematic top view illustrating an electronic device according to an embodiment of the disclosure.

### DESCRIPTION OF THE EMBODIMENTS

The disclosure may be understood by referring to the following detailed description in conjunction with the drawings. It should be noted that in order to facilitate the understanding by the reader and the conciseness of the drawings, multiple drawings in the disclosure only depict a part of an electronic device, and specific elements in the drawings are not drawn according to actual scale. In addition, the number and the size of each element in the drawings are only for illustration and are not intended to limit the scope of the disclosure.

Throughout the specification and the appended claims of the disclosure, certain words are used to refer to specific elements. Persons skilled in the art should understand that electronic device manufacturers may refer to the same elements by different names. The disclosure does not intend to distinguish the elements with the same function but different names.

In the following specification and claims, words such as “containing” and “comprising” are open-ended words, which should be interpreted as “including but not limited to . . . ”.

In addition, relative terms, such as “below” or “bottom portion” and “above” or “top portion”, may be used in the embodiments to describe the relative relationship of one element to another element of the drawings. It should be understood that if a device in the drawings is turned upside down, elements described as “below” will become elements described as “above”.

In some embodiments of the disclosure, terms related to bonding and connection, such as “connection” and “interconnection”, unless otherwise defined, may refer to two structures that are directly in contact or may also refer to two structures that are not directly (indirectly) in contact, wherein there is another structure provided between the two structures. Also, the terms related to bonding and connection may also include the case where two structures are both movable or two structures are both fixed. Furthermore, the term “coupling” includes the transfer of energy between two structures by means of direct or indirect electrical connection or the transfer of energy between two separate structures by means of mutual induction.

It should be understood that when an element or a layer is referred to as being “on” or “connected to” another element or layer, the element may be directly on the other element or layer or directly connected to the other element or layer, or there is an intervening element or layer between the two (indirect case). In contrast, when an element is referred to as being “directly on” or “directly connected to” another element or layer, there is no intervening element or layer between the two.

The terms “about”, “equal to”, “equivalent” or “same”, or “substantially” or “roughly” are generally interpreted as within 20% of a given value or range, or interpreted as within 10%, 5%, 3%, 2%, 1%, or 0.5% of the given value or range.

As used herein, the terms “film” and/or “layer” may refer to any continuous or discontinuous structure and material (such as a material deposited by a method disclosed herein). For example, the film and/or the layer may include a two-dimensional material, a three-dimensional material, nanoparticles, or even a part of or a complete molecular layer, a part of or a complete atomic layer, or atomic and/or molecular clusters. The film or the layer may contain a material or a layer having pinholes, which may be at least partially continuous.

Although the terms first, second, third . . . may be used to describe various constituent elements, the constituent elements are not limited by the terms. The terms are only used to distinguish a single constituent element from other constituent elements in the specification. The same terms may not be used in the claims, but replaced by first, second, third . . . according to the order in which the elements are declared in the claims. Therefore, in the following specification, a first constituent element may be a second constituent element in the claims.

Unless otherwise defined, all terms (including technical and scientific terms) used herein have the same meaning as commonly understood by persons skilled in the art to which the disclosure belongs. It should be understood that the terms, such as those defined in commonly used dictionaries, should be interpreted as having meanings consistent with the prior art and the background or context of the disclosure, and should not be interpreted in an idealized or overly formal manner, unless specifically defined herein.

It should be noted that in the following embodiments, the technical features of several different embodiments may be replaced, reorganized, and mixed to complete other embodiments without departing from the spirit of the disclosure.

An electronic device of the disclosure may include a display device, an antenna device, a sensing device, a light emitting device, or a splicing device, but not limited thereto. The electronic device may include a bendable or flexible electronic device. The electronic device may include an electronic element. The electronic element may include a passive element, an active element, or a combination thereof, such as a capacitor, a resistor, an inductor, a variable capacitor (varactor), a filter, a diode, a transistor, a sensor, micro-electro mechanical systems (MEMS), and a liquid crystal chip, but not limited thereto. The diode may include a light emitting diode or a non-light emitting diode. The diode may include, for example, a P-N junction diode, a PIN diode, or a constant current diode. The light-emitting diode may include, for example, an organic light emitting diodes (OLED), a mini LED, a micro LED, a quantum dot LED, fluorescence, phosphor, other suitable materials, or a combination of the above, but not limited thereto. The sensor may include, for example, a capacitive sensor, an optical sensor, an electromagnetic sensor, a fingerprint sensor (FPS), a touch sensor, an antenna, a pen sensor, etc., but not limited thereto. In the following, the disclosure will be described with the electronic device being a display device. However, the disclosure is not limited thereto.

Reference will now be made in detail to the exemplary embodiments of the disclosure, examples of which are illustrated in the drawings. Wherever possible, the same reference numerals are used in the drawings and the description to refer to the same or similar parts.

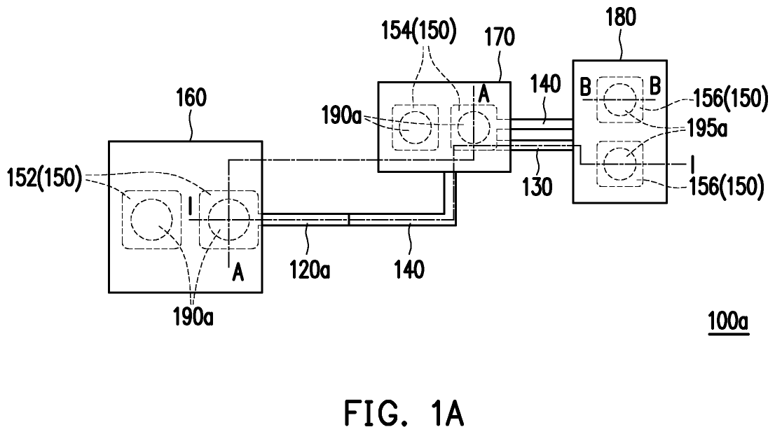

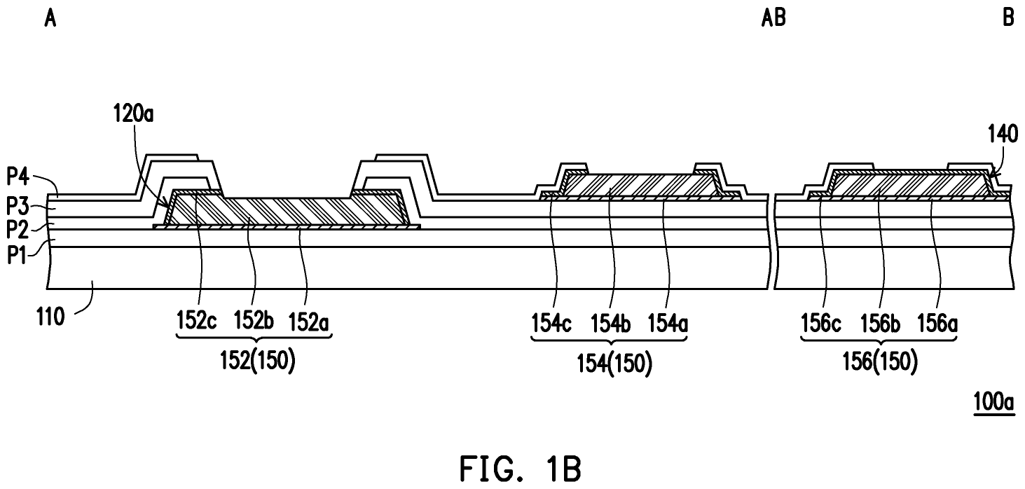

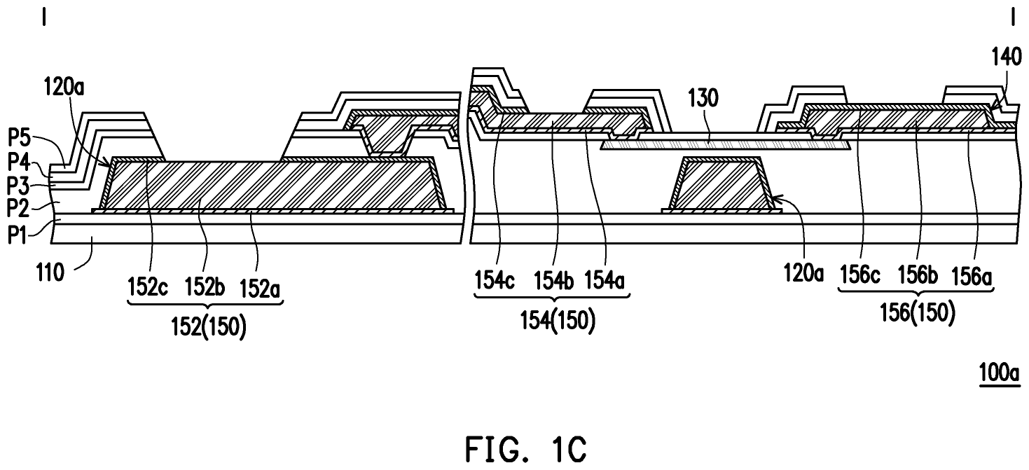

FIG. 1A is a schematic top view illustrating an electronic device according to an embodiment of the disclosure. FIG. 1B is a schematic cross-sectional view taken along line A-A and line B-B in FIG. 1A. FIG. 1C is a schematic cross-sectional view taken along line I-I in FIG. 1A. For the ease of description, FIG. 1A, FIG. 1B, and FIG. 1C respectively leave some elements unillustrated.

Referring to FIG. 1A, FIG. 1B, and FIG. 1C at the same time, in the embodiment, an electronic device 100a includes a substrate 110, a first metal layer 120a, a second metal layer 130, a third metal layer 140, multiple pads 150, an electronic element 160, and a switching element 170. The first metal layer 120a is disposed on the substrate 110. The second metal layer 130 is disposed on the substrate 110. The third metal layer 140 is disposed on the substrate 110. The pads 150 are disposed on the substrate 110, including a first pad 152, a second pad 154, and a third pad 156. The electronic element 160 is disposed on the substrate 110 and connected to the first pad 152. The switching element 170 is disposed on the substrate 110 and connected to the second pad 154. The second metal layer 130 is disposed between the first metal layer 120a and the third metal layer 140. The first pad 152 and the first metal layer 120a belong to the same layer, and the first pad 152 is electrically connected to the second pad 154 through the first metal layer 120a and the third metal layer 140.

Specifically, in the embodiment, the substrate 110 may include, for example, a glass substrate, a glass fiber (FR4) substrate, a ceramic substrate, a flexible plastic substrate, a thin-film substrate, a flexible substrate, a printed circuit board, a redistribution layer (RDL) substrate, or other suitable substrates. However, the disclosure is not limited thereto. The first metal layer 120a, the second metal layer 130, and the third metal layer 140 are disposed on the substrate 110 in succession. The second metal layer 130 and the scan line belong to the same layer, for example, and the third metal layer 140 and the data line belong to the same layer, for example. However, the disclosure not limited thereto.

In the embodiment, the electronic device 100a further includes a first insulation layer P1, a second insulation layer P2, a third insulation layer P3, and a fourth insulation layer P4. The first insulation layer P1 is disposed on the substrate 110 and located between the substrate 110 and the first metal layer 120a. The first insulation layer P1 is a stress adjustment film for stress balancing of the first metal layer 120a and the substrate 110 and is able to protect the first metal layer 120a. The material of the first insulation layer P1 includes, for example, silicon nitride (SiNx), but the disclosure is not limited thereto. The first metal layer 120a is located between the first insulation layer P1 and the second insulation layer P2. The second metal layer 130 is located between the second insulation layer P2 and the third insulation layer P3. The third metal layer 140 is located between the third insulation layer P3 and the fourth insulation layer P4. The second insulation layer P2 is provided for passivation of the first metal layer 120a, the third insulation layer P3 is provided for passivation of the second metal layer 130, and the fourth insulation layer P4 is provided for passivation of the third metal layer 140. A portion of the third insulation layer P3 and the fourth insulation layer P4 expose a portion of the first metal layer 120a and therefore defines the first pad 152, and the fourth insulation layer P4 exposes a portion of the third metal layer 140 and therefore defines the second pad 154 and the third pad 156. In an embodiment, the first insulation layer P1, the second insulation layer P2, the third insulation layer P3, and the fourth insulation layer P4 may respectively include suitable insulation materials, e.g., silicon nitride, dielectric, polymer, organic material, or polyimide. However, the disclosure is not limited thereto. In an embodiment, the electronic device 100a further includes a fifth insulation layer P5, disposed on the fourth insulation layer P4.

In short, on the substrate 110 of the embodiment, three metal layers (i.e., the first metal layer 120a, the second metal layer 130, and the third metal layer 140), and four insulation layers (i.e., the first insulation layer P1, the second insulation layer P2, the third insulation layer P3, and the fourth insulation layer P4) are formed. If the material of the substrate 110 includes glass, the substrate 110 may be considered as a glass circuit board.

Referring to FIG. 1A and FIG. 1B again, in the embodiment, the second pad 154, the third pad 156, and the third metal layer 140 belong to the same layer, and the second pad 154 is electrically connected to the third pad 156 through the second metal layer 130. More specifically, the first pad 152 in the embodiment includes, for example, a first titanium nitride layer 152a, a copper layer 152b, and a second titanium nitride layer 152c. In other words, the first pad 152 has three structural layers, a portion of the third insulation layer P3 and the fourth insulation layer P4 exposes a portion of the copper layer 152b of the first pad 152. The first pad 152 and the first metal layer 120a belong to the same layer, and thus the first metal layer 120a also has three structural layers. The second pad 154 includes, for example, a titanium nitride layer 154a, a copper layer 154b, and a titanium layer 154c. In other words, the second pad 154 has three structural layers, and the fourth insulation layer P4 exposes a portion of the copper layer 154b of the second pad 154. The third pad 156 includes a titanium nitride layer 156a, a copper layer 156b, and a titanium layer 156c. In other words, the third pad 156 has three structural layers, and the fourth insulation layer P4 exposes a portion of the titanium layer 156c of the third pad 156.

Referring to FIG. 1A again, the electronic device 100a of the embodiment further includes a circuit board 180 that is disposed on the substrate 110 and connected to the third pad 156. Moreover, the electronic device 100a of the embodiment further includes multiple first conductive structures 190a and a second conductive structure 195a. The first conductive structures 190a are respectively disposed between the electronic element 160 and the first pad 152 and between the switching element 170 and the second pad 154. The electronic element 160 is electrically connected to the first pad 152 through the first conductive structure 190a. The switching element 170 is electrically connected to the second pad 154 through the first conductive structure 190a. The second conductive structure 195a is disposed between the circuit board 180 and the third pad 156. The circuit board 180 is electrically connected to the third pad 156 through the second conductive structure 195a. In an embodiment, the first conductive structures 190a may be, for example, electroless nickel immersion gold bumps or metal pillars, and the second conductive structure 195a may be, for example, an electroless nickel immersion gold bump, an anisotropic conductive layer, or a metal pillar.

The electronic element 160 of the embodiment is connected to the first pad 152 through the first conductive structure 190a, and the electronic element 160 may include a passive element or an active element, e.g., a capacitor, a resistor, an inductor, a varactor, a filter, a diode, a transistor, a sensor, a microelectromechanical system (MEMS) element, a liquid crystal chip, etc.

The switching element 170 of the embodiment is connected to the second pad 154 through the first conductive structure 190a. The switching element 170 includes a TFT element, a metal oxide semiconductor field effect transistor (MOSFET) element, or an integrated circuit and may be, for example, a chip or package bonded through surface mounting technology (SMT) or chip-on-board (COB) package.

The circuit board 180 of the embodiment is connected to the third pad 156 through the second conductive structure 195a, and the circuit board 180 is, for example, a reel-to-reel chip on film (COF) or chip on glass (COG).

In short, the switching element 170 of the embodiment is connected to the second pad 154 through bonding. Hence, in comparison with the conventional technique, which manufactures a driver element on a glass substrate, the electronic device 100a of the embodiment is manufactured through simple process and effectively reduces manufacturing cost. Moreover, the first pad 152 and the first metal layer 120a of the embodiment belong to the same layer and the first pad 152 is electrically connected to the second pad 154 through the first metal layer 120a and the third metal layer 140. Through the design of sharing the same layer, the electronic device 100a of the embodiment requires less usage of photomask in manufacturing process and thus effectively reduces production cost.

It should be specified that the reference numerals and a part of the contents in the previous embodiment are used in the following embodiments, in which identical reference numerals indicate identical or similar elements, and repeated description of the same technical contents is omitted. For a detailed description of the omitted parts, reference can be found in the previous embodiment, and no repeated description is contained in the following embodiments.

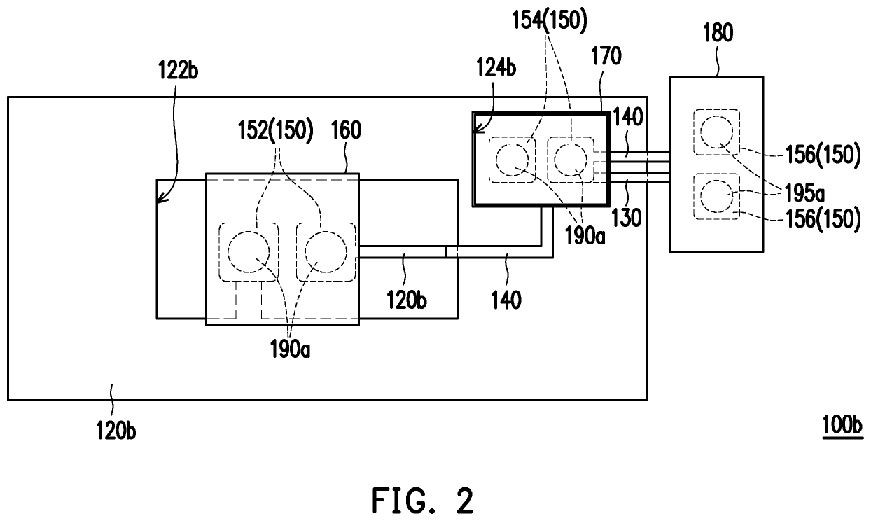

FIG. 2 is a schematic top view illustrating an electronic device according to another embodiment of the disclosure. Referring to FIG. 1A and FIG. 2 at the same time, an electronic device 100b is similar to the electronic device 100a in FIG. 1A. The difference between the two devices lies in that in the embodiment, to avoid affecting the electronic element 160 and the switching element 170, the first metal layer 120b may be a copper layer with a whole layer structure having an opening. Specifically, the first metal layer 120b of the embodiment has an opening 122b and an opening 124b, the first pad 152 is located inside the opening 122b and the second pad 154 is located in the opening 124b. An orthographic projection of the second pad 154 on the substrate 110 does not overlap an orthographic projection of the first metal layer 120b on the substrate 110. The opening 122b herein is larger than the opening 124b in size yet is not limited thereto.

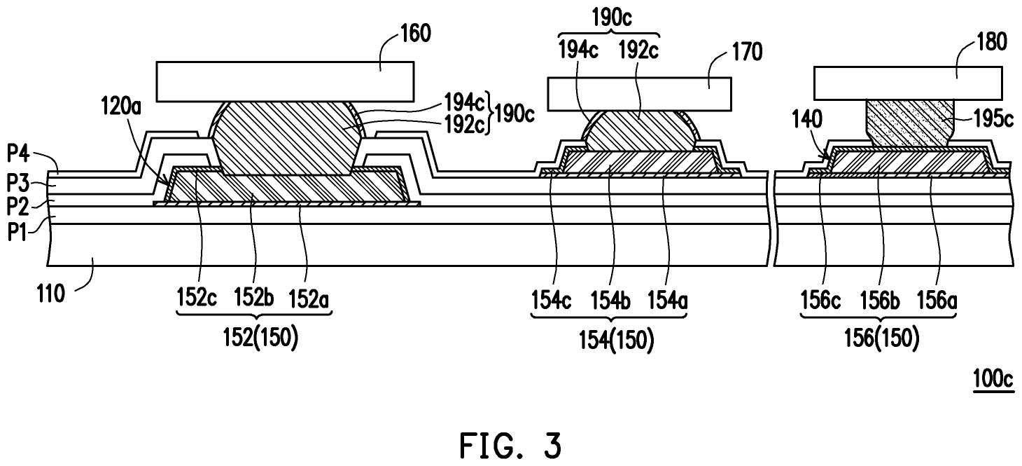

FIG. 3 is a schematic cross-sectional view illustrating an electronic device according to another embodiment of the disclosure. Referring to FIG. 1A and FIG. 3 at the same time, the electronic device 100c is similar to the electronic device 100a in FIG. 1A. The difference between the two devices lies in that a first conductive structure 190c of the electronic device 100c in the embodiment is, for example, an electroless nickel immersion gold (ENIG) bump and a second conductive structure 195c is, for example, an anisotropic conductive film (ACF). The first conductive structure 190c is described as including a nickel layer 192c and a gold layer 194c. The nickel layer 192c directly contacts the electronic element 160 as well as the copper layer 152b and the second titanium nitride layer 152c of the first pad 152, and the gold layer 194c covers the nickel layer 192c, so as to electrically connect the electronic element 160 and the first pad 152. The nickel layer 192c directly contacts the switching element 170 as well as the copper layer 154b and the titanium layer 154c of the second pad 154, and the gold layer 194c covers the nickel layer 192c, so as to electrically connect the switching element 170 and the second pad 154. The second conductive structure 195c directly contacts the circuit board 180 and the titanium layer 156c of the third pad 156, so as to electrically connect the circuit board 180 and the third pad 156.

In the embodiment, since the second pad 154, the third pad 156, and the third metal layer 140 belong to the same layer (i.e., the third metal layer 140 also having three structure layers), through an attachment force between the third metal layer 140 and the insulation layer that includes, for example, silicon nitride, ENIG micro-etching Cu/SiNx side etching may be improved. The third metal layer 140 may serve as a bonding layer for ENIG, and through layered etching, a titanium interface (e.g., the titanium layer 156c) of the third metal layer 140 may replace an indium tin oxide (ITO) layer available in the conventional techniques to serve as an adhesion layer of anisotropic conductive layer.

In the embodiment, although the second conductive structure 195c is described as an anisotropic conductive film (ACF), the disclosure is not limited thereto. In another embodiment, the second conductive structure may be an electroless nickel immersion gold (ENIG) bump same as the first conductive structure and still falls within the scope of the disclosure.

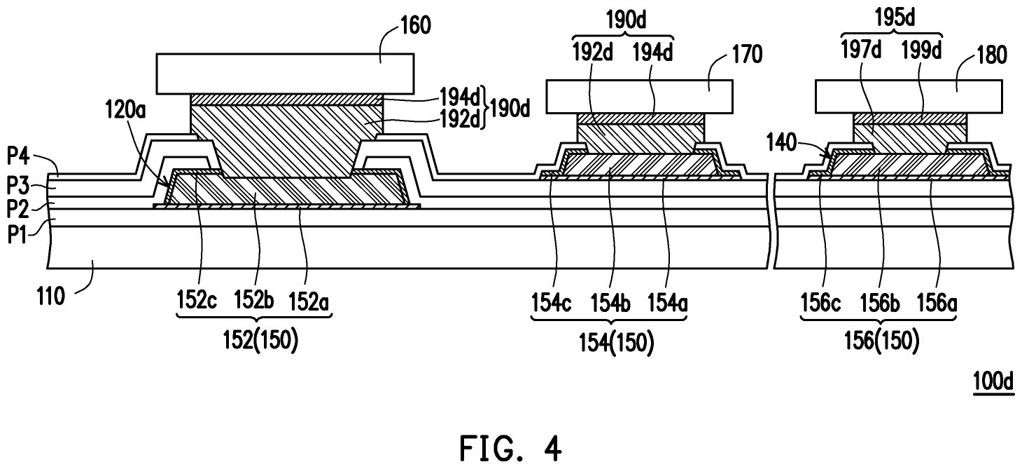

FIG. 4 is a schematic cross-sectional view illustrating an electronic device according to another embodiment of the disclosure. Referring to FIG. 3 and FIG. 4 at the same time, an electronic device 100d is similar to the electronic device 100c in FIG. 3. The difference between the two devices lies in that in the embodiment, first conductive structures 190d and a second conductive structure 195d of the electronic device 100d are respectively, for example, metal pillars. Specifically, the first conductive structure 190d includes a copper layer 192d and a tin-silver layer 194d, the tin-silver layer 194d is located on the copper layer 192d, the copper layer 192d directly contacts the copper layer 152b and the second titanium nitride layer 152c of the first pad 152, and the tin-silver layer 194d directly contacts the electronic element 160, so as to electrically connect the electronic element 160 and the first pad 152. The copper layer 192d directly contacts the copper layer 154b and the titanium layer 154c of the second pad 154, and the tin-silver layer 194d directly contacts the switching element 170, so as to electrically connect the switching element 170 and the second pad 154. The second conductive structure 195d includes a copper layer 197d and a tin-silver layer 199d, the tin-silver layer 199d is located on the copper layer 197d, the copper layer 197d directly contacts the titanium layer 156c of the third pad 156, and the tin-silver layer 199d directly contacts the circuit board 180, so as to electrically connect the circuit board 180 and the third pad 156.

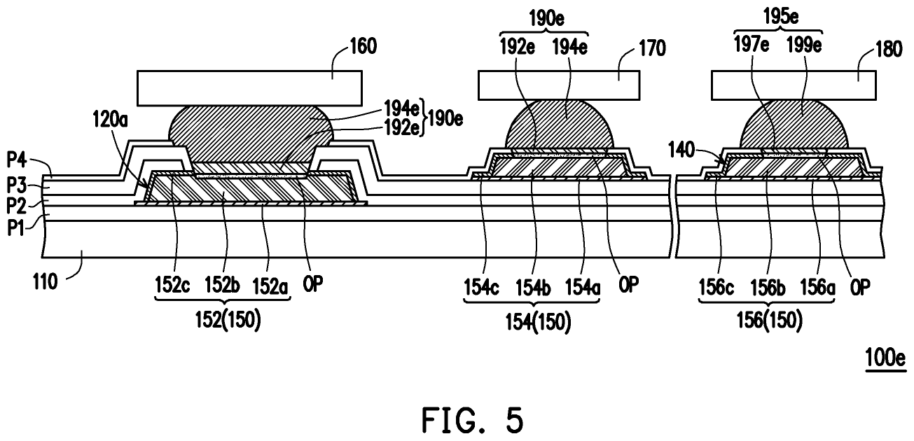

FIG. 5 is a schematic cross-sectional view illustrating an electronic device according to another embodiment of the disclosure. Referring to FIG. 3 and FIG. 5 at the same time, an electronic device 100e is similar to the electronic device 100c in FIG. 3. The difference between the two devices lies in that in the embodiment, first conductive structures 190e and a second conductive structure 195e of the electronic device 100e are respectively solder balls. Specifically, the first conductive structure 190e includes a nickel layer 192e and a tin-silver layer 194e, and the second conductive layer 195e includes a nickel layer 197e and a tin-silver layer 199e. In an embodiment, the tin-silver layer 194e is located on the nickel layer 192e, the nickel layer 192e directly contacts the copper layer 152b and the second titanium nitride layer 152c of the first pad 152, and the tin-silver layer 194e directly contacts the electronic element 160, so as to electrically connect the electronic element 160 and the first pad 152. The nickel layer 192e directly contacts the copper layer 154b and the titanium layer 154c of the second pad 154, and the tin-silver layer 194e directly contacts the switching element 170, so as to electrically connect the switching element 170 and the second pad 154. The tin-silver layer 199e is located on the nickel layer 197e, the nickel layer 197e directly contacts the titanium layer 156c of the third pad 156, and the tin-silver layer 199e directly contacts the circuit board 180, so as to electrically connect the circuit board 180 and the third pad 156. In another embodiment, the electronic device 100e may selectively include protection layers OP disposed between the first conductive structure 190e and the first pad 152, between the first conductive structure 190e and the second pad 154, and between the second conductive structure 195e and the third pad 156. The protection layers OP are, for example, organic solderability preservative (OSP) films, and the material of the protection layer OP may include copper-tin alloy. However, the disclosure is not limited thereto.

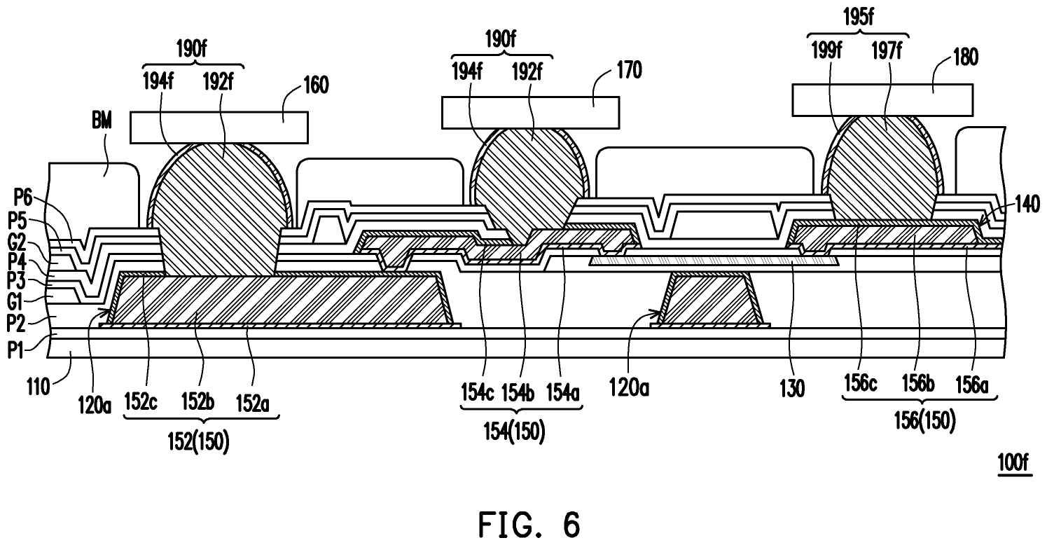

FIG. 6 is a schematic cross-sectional view illustrating an electronic device according to another embodiment of the disclosure. Referring to FIG. 3 and FIG. 6 at the same time, an electronic device 100f is similar to the electronic device 100c in FIG. 3. The difference between the two devices lies in that in the embodiment, the electronic device 100f further includes a protection layer G1, a protection layer G2, the fifth insulation layer P5, a sixth insulation layer P6, and a protection layer BM. Specifically, the protection layer G1 is disposed between the first metal layer 120a and the second metal layer 130, and reduces or decreases short-circuiting between the second metal layer 130 and the first metal layer 120a. The protection layer G2 is disposed between the fourth insulation layer P4 and the fifth insulation layer P5. In an embodiment not shown herein, protection layers may also be disposed between the first metal layer and the second metal layer and also between the first metal layer and the third metal layer to reduce or decrease short-circuiting between the second metal layer and the first metal layer and between the third metal layer and the first metal layer. The materials of the protection layer G1 and the protection layer G2 may include, for example, polyimide (PI) or perfluoroalkoxy (PFA). However, the disclosure is not limited thereto. The third metal layer 140 is located between the third insulation layer P3 and the fourth insulation layer P4, the sixth insulation layer P6 exposes the copper layer 154b and the titanium layer 154c of the second pad 154, the fourth insulation layer P4 exposes the titanium layer 156c of the third pad 156. The protection layer BM covers the sixth insulation layer P6 and reduces risk of short-circuiting among the first metal layer 120a, the second metal layer 130, and the third metal layer 140. The material of the protection layer BM may include, for example, solder resist (SR) or black matrix (BM). However, the disclosure is not limited thereto. Moreover, a first conductive structure 190f is described as including a nickel layer 192f and a gold layer 194f. The nickel layers 192f are located on the first pad 152 and also on the second pad 154, and the gold layers 194f cover the nickel layers 192f. The second conductive structure 195f is described as including a nickel layer 197f and a gold layer 199f, the nickel layer 197f is located on the third pad 156 and the gold layer 199f covers the nickel layer 197f.

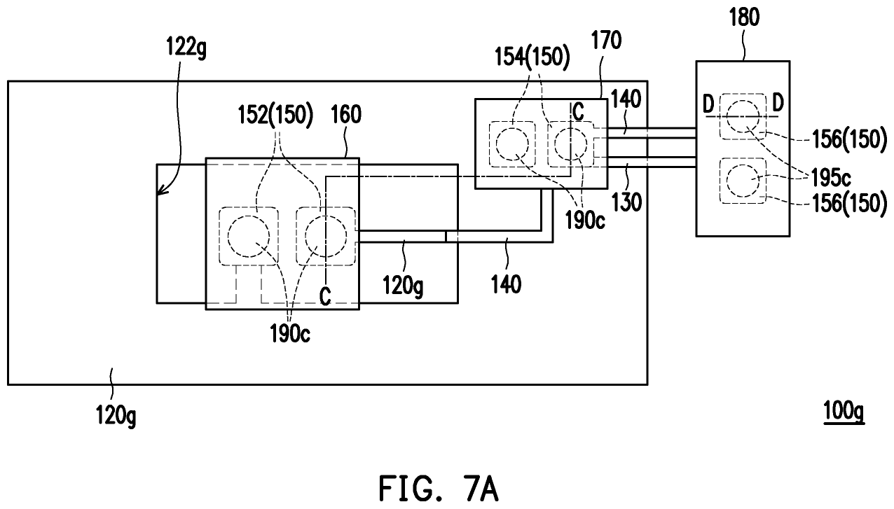

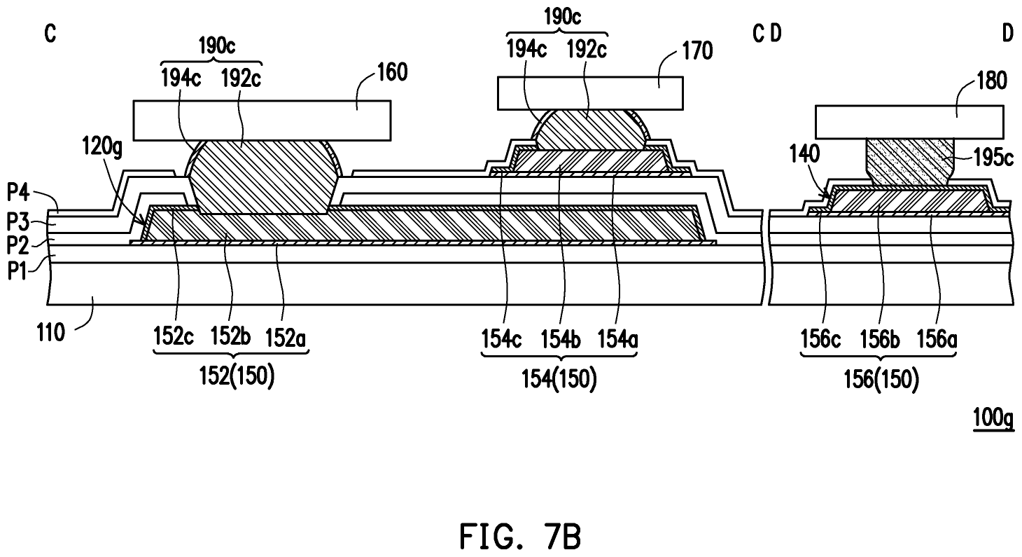

FIG. 7A is a schematic top view illustrating an electronic device according to an embodiment of the disclosure. FIG. 7B is a schematic cross-sectional view taken along line C-C and line D-D in FIG. 7A. Referring to FIG. 3, FIG. 7A, and FIG. 7B at the same time, an electronic device 100g is similar to the electronic device 100c in FIG. 3. The difference between the two devices lies in that in the embodiment, the electronic device 100g may be, for example, an antenna device, the first pad 152 is located inside an opening 122g of the first metal layer 120g and the orthographic projection of the second pad 154 on the substrate 110 overlaps an orthographic projection of the first metal layer 120g on the substrate 110. In other words, no opening is provided at the position of the first metal layer 120g corresponding to the second pad 154 and therefore, EMI shielding effect is reduced.

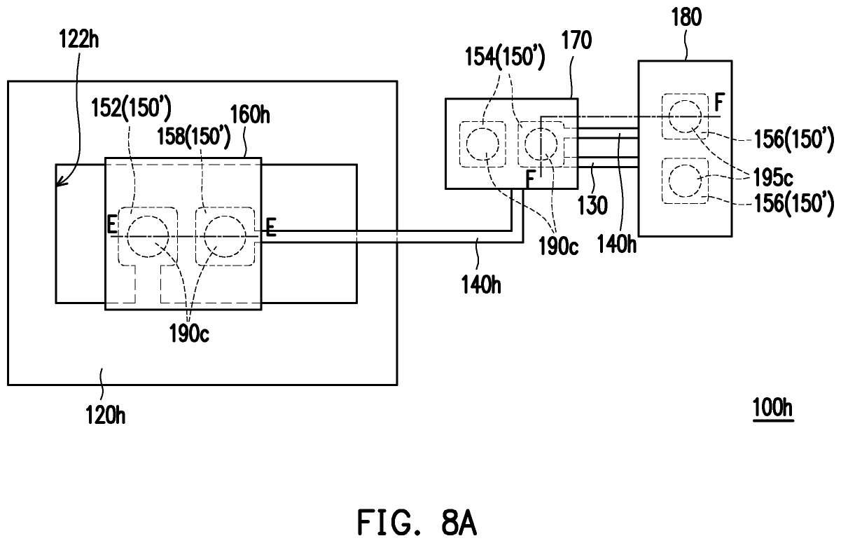

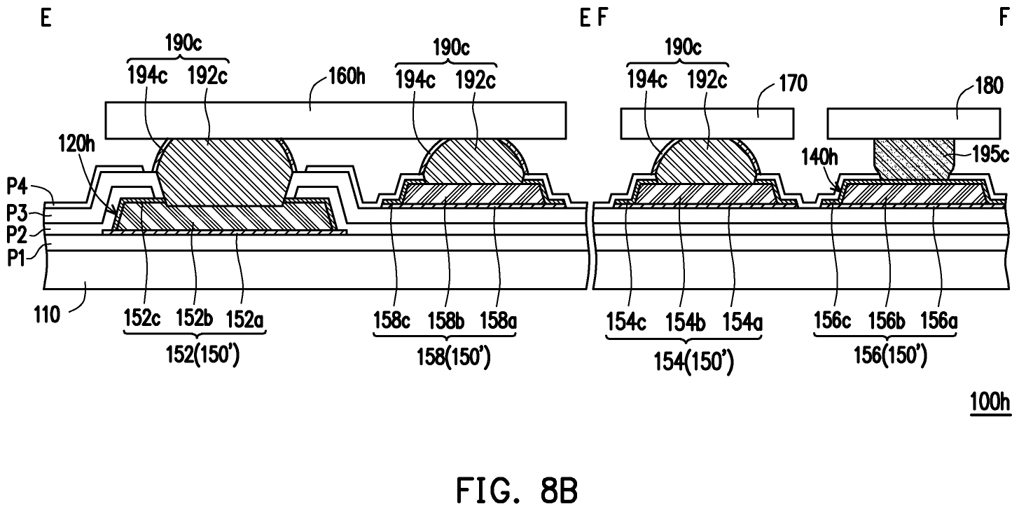

FIG. 8A is a schematic top view illustrating an electronic device according to an embodiment of the disclosure. FIG. 8B is a schematic cross-sectional view taken along line E-E and line F-F in FIG. 8A. Referring to FIG. 3, FIG. 8A, and FIG. 8B at the same time, an electronic device 100h is similar to the electronic device 100c in FIG. 3. The difference between the two devices lies in that in the embodiment, one of pads 150′ of the electronic device 100h further include a fourth pad 158, and the fourth pad 158 and a third metal layer 140h belong to the same layer and are located inside an opening 122h of a first metal layer 120h. The fourth pad 158 is electrically connected to the second pad 154 through the third metal layer 140h, and the fourth pad 158 includes a titanium nitride layer 158a, a copper layer 158b, and a titanium layer 158c. The fourth insulation layer P4 exposes a portion of the copper layer 158b of the fourth pad 158, the nickel layer 192c of the first conductive structure 190c directly contacts an electronic element 160h and the copper layer 158b of the fourth pad 158, the gold layer 194c covers the nickel layer 192c, so as to electrically connect the electronic element 160h and the fourth pad 158. The electronic element 160h of the embodiment is connected onto the first pad 152 and the fourth pad 158 through the first conductive structures 190c. In other words, the electronic element 160h is able to be electrically connected to pads of different layers.

In an embodiment not shown herein, the first metal layer may also extend to be under the fourth pad. In other words, an orthographic projection of the fourth pad on the first metal layer overlaps the first metal layer, and this still falls within the scope of the disclosure.

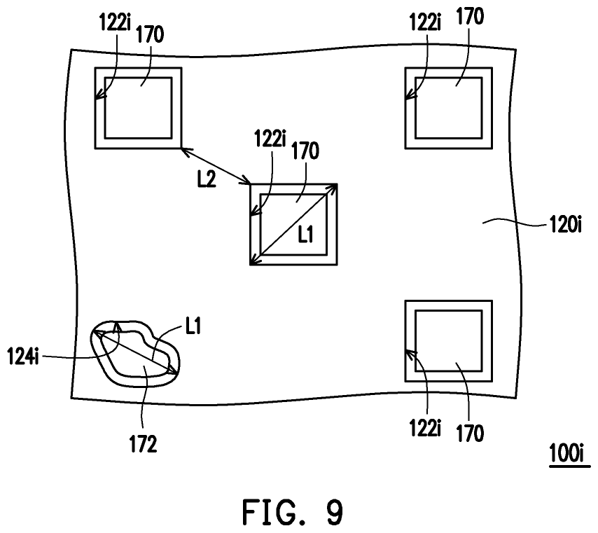

FIG. 9 is a partial schematic top view illustrating an electronic device according to an embodiment of the disclosure. Referring to FIG. 1A and FIG. 9 at the same time, an electronic device 100i is similar to the electronic device 100a in FIG. 1A. The difference between the two devices lies in that in the embodiment, a first metal layer 120i of the electronic device 100i has multiple openings 122i and 124i, orthographic projections of the switching elements 170 on the first metal layer 120i are located inside the openings 122i, and an orthographic projection of a switching element 172 on the first metal layer 120i is located inside the opening 124i. From a top view, the openings 122i are rectangular and the opening 124i is irregular in shape, for example. A maximum length L1 of each of the openings 122i and 124i is, for example, shorter than 3 micrometers. A distance L2 between two openings 122i is at least 3.5 micrometers. In other words, the distance L2 must be greater than an electromagnetic wavelength of 3 micrometers. The switching elements 170 and 172 are respectively located in the openings 122i and 124i. Through the design of the openings 122i and 124i, EMI shielding effect on the switching elements 170 and 172 is reduced.

In a nutshell, in the embodiments of the disclosure, the switching element is connected to the second pad through bonding, the first pad and the first metal layer belong to the same layer and the first pad is electrically connected to the second pad through the first metal layer and the third metal layer. Through connecting of the switching element and design of sharing the same layer, the electronic device of the disclosure effectively reduces production cost.

Finally, it should be noted that the above embodiments merely serve to illustrate the technical schemes of the disclosure rather than limiting the disclosure. Although the disclosure has been described in detail with reference to the foregoing embodiments, those of ordinary skill in the pertinent art should understand that it is possible to modify the technical schemes described in the foregoing embodiments or equivalently replace some or all of the technical features; and these modifications or replacements do not make the nature of the corresponding technical schemes deviate from the technical schemes of the embodiments provided in the disclosure.

What is claimed is:

1. An electronic device, comprising:
a substrate;
a first metal layer, disposed on the substrate;
a second metal layer, disposed on the substrate;
a third metal layer, disposed on the substrate;
a plurality of pads, disposed on the substrate, and comprising a first pad, a second pad, and a third pad;
an electronic element, disposed on the substrate and connected to the first pad; and
a switching element, disposed on the substrate and connected to the second pad, wherein the second metal layer is disposed between the first metal layer and the third metal layer, the first pad and the first metal layer belong to the same layer, and the first pad is electrically connected to the second pad through the first metal layer and the third metal layer.

2. The electronic device according to claim 1, wherein an orthographic projection of the second pad on the substrate does not overlap an orthographic projection of the first metal layer on the substrate.

3. The electronic device according to claim 1, wherein an orthographic projection of the second pad on the substrate overlaps an orthographic projection of the first metal layer on the substrate.

4. The electronic device according to claim 1, further comprising:
at least one protection layer, at least disposed between the first metal layer and the second metal layer.

5. The electronic device according to claim 1, wherein the second pad, the third pad, and the third metal layer belong to the same layer and the second pad is electrically connected to the third pad through the second metal layer.

6. The electronic device according to claim 1, further comprising:
a circuit board, disposed on the substrate and connected to the third pad.

7. The electronic device according to claim 6, further comprising:
a plurality of first conductive structures, respectively disposed between the electronic element and the first pad and between the switching element and the second pad; and
a second conductive structure, disposed between the circuit board and the third pad.

8. The electronic device according to claim 7, wherein each of the first conductive structures and the second conductive structure respectively comprises a solder ball.

9. The electronic device according to claim 8, further comprising:
at least one protection layer, disposed between each of the first conductive structures and the first pad, between each of the first conductive structures and the second pad, and between the second conductive structure and the third pad.

10. The electronic device according to claim 9, wherein a material of the at least one protection layer comprises polyimide (PI) or perfluoroalkoxy (PFA).

11. The electronic device according to claim 7, wherein the first conductive structures comprise a plurality of electroless nickel immersion gold bumps or a plurality of metal pillars and the second conductive structure comprises an electroless nickel immersion gold bump, an anisotropic conductive layer, or a metal pillar.

12. The electronic device according to claim 6, wherein the circuit board comprises a reel-to-reel chip on film (COF) or chip on glass (COG).

13. The electronic device according to claim 1, further comprising:
a first insulation layer, a second insulation layer, a third insulation layer, and a fourth insulation layer, wherein the first insulation layer is disposed on the substrate and located between the substrate and the first metal layer, the first metal layer is located between the first insulation layer and the second insulation layer, the second metal layer is located between the second insulation layer and the third insulation layer, and the third metal layer is located between the third insulation layer and the fourth insulation layer.

14. The electronic device according to claim 13, wherein a material of the first insulation layer, a material of the second insulation layer, a material of the third insulation layer, and a material of the fourth insulation layer comprise silicon nitride, dielectric, polymer, organic material, or polyimide.

15. The electronic device according to claim 1, wherein the first pad comprises a first titanium nitride layer, a copper layer, and a second titanium nitride layer.

16. The electronic device according to claim 1, wherein the second pad comprises a titanium nitride layer, a copper layer, and a titanium layer.

17. The electronic device according to claim 1, wherein the third pad comprises a titanium nitride layer, a copper layer, and a titanium layer.

18. The electronic device according to claim 1, wherein the electronic element comprises a passive element or an active element.

19. The electronic device according to claim 1, wherein the switching element comprises a thin-film transistor (TFT) element, a metal oxide semiconductor field effect transistor (MOSFET) element, or an integrated circuit.

20. The electronic device according to claim 1, wherein the first metal layer has two openings, the first pad and the second pad are respectively located in the two openings and an orthographic projection of the second pad on the substrate does not overlap an orthographic projection of the first metal layer on the substrate.
